(19) United States
(12) Patent Application Publication
(10) Pub. No.: US 2007/0040182 A1
(43) Pub. Date: Feb. 22, 2007

(54) Light emitting diode packaging structure

(76) Inventor: Julian Lee, Taipei Hsien (TW)

Correspondence Address: PRO-TECHTOR INTERNATIONAL SERVICES, 20775 NORADA CT., SARATOGA, CA, 95070, US

(21) Appl. No.: 11/204,950

(22) Filed: Aug. 16, 2005

(51) Int. Cl. H01L 33/00

(52) U.S. Cl. 257/98

(57) ABSTRACT

A light emitting diode (LED) packaging structure has a carrier having an insulating layer and a conducting layer formed thereon. A top surface of the carrier is partially depressed to form a cup portion having a raised central seat upward projected from a bottom thereof. The raised central seat has a top preferably flush with or higher than the conducting layer. An LED chip is mounted on the top of the raised central seat to enable improved light emitting and heat radiating effects. An encapsulating resin encapsulates and protects the LED chip, and a light-gathering hood is attached to the carrier corresponding to the encapsulating resin.

### FIELD OF THE INVENTION

The present invention relates to a packaging structure, and more particularly to a packaging structure for light emitting diode to enhance the light emitting and heat radiating effects of the light emitting diode.

### BACKGROUND OF THE INVENTION

A light emitting diode (LED) has relatively long usable life, and low power consumption, and is therefore widely utilized in industrial fields to replace other high power-consuming light-emitting elements in response to the constantly increasing energy cost.

FIG. 1 is a sectional view showing a conventional LED packaging structure 1 that includes a carrier 11, an LED chip 12, and an encapsulating resin 13. The carrier 11 is provided on a top surface with an insulating layer 111, and a conducting layer 112 consisting of conducting circuits is further provided on a top surface of the insulating layer 111. The top surface of the carrier 11 is partially depressed to form a cup portion 113. The LED chip 12 is mounted on a bottom 114 of the cup portion 113 and electrically connected at two electrodes to the conducting layer 112 via two conductors 121. The encapsulating resin 13 encapsulates the LED chip 12 and the conductors 121. When the LED chip 12 is supplied with electric power via the conductors 121 and the conducting layer 112, lights are emitted from top and peripheral wall of the LED chip 12. In the conventional LED packaging structure 1, since the LED chip 12 is mounted on the bottom 114 of the cup portion 113 of the carrier 11, only the light emitted from the top of the LED chip 12 could radiate without being hindered by the cup portion 113 surrounding the LED chip 12. Most part of lights emitted from the peripheral wall of the LED chip 12 are reflected by an inner wall 115 of the cup portion 113 before they could radiate out of the cup portion 113. Since lights emitted from different areas of the LED chip 12 have different incident angles and reflection angles, they tend to interfere with one another when they travel forward and are therefore subjected to light loss or lowered light flux. In other words, being affected by reflection interference and light loss, at best only 90% of the light flux produced by the light emitting LED chip 12 in the conventional LED packaging structure 1 can be radiated. The other part of emitted lights is lost in the process of reflection interference to adversely reduce the brightness of lights emitted from the LED chip 12.

Further, heat and high temperature is produced when the LED chip 12 works to transform electric energy into light energy. The brightness of the LED chip 12 decreases 0.9% when the temperature rises 1° C. It is obvious the brightness of an LED is significantly influenced by the temperature-rise effect.

As can be seen from FIG. 1, since the LED chip 12 is mounted on and in contact with the bottom 114 of the cup portion 113, the bottom 114 and the inner wall 115 of the cup portion 113 together provide an area for radiating heat produced by the LED chip 12. However, the heat radiating area provided by the cup portion 113 is too small to produce good heat radiating effect, which also has reverse influence on the brightness of the LED chip 12.

### SUMMARY OF THE INVENTION

A primary object of the present invention is to provide an LED packaging structure that enables reduced reflection loss and thereby better light flux to enhance the light emitting effect of an LED.

Another object of the present invention is to provide an LED packaging structure that provides better heat radiating power and thereby enables enhanced light emitting effect and increased usable life of an LED.

To achieve the above and other objects, the LED packaging structure according to the present invention includes a carrier and an LED chip. The carrier has an insulating layer and a conducting layer provided thereon. A top of the carrier is partially depressed to form a cup portion having a raised central seat upward projected from a bottom thereof. The raised central seat has a top preferably flush with or higher than the conducting layer. The LED chip is mounted on the top of the raised central seat, and lights emitted from the top and the peripheral wall of the LED chip are not hindered by the inner wall of the cup portion and not subjected to reflection loss. Therefore, the LED chip provides better light flux and enhanced light emitting effect. Moreover, the raised central seat provides increased heat radiating area for the LED chip, enabling the LED packaging structure to have improved heat-radiating power, which further enhances the light emitting effect and the usable life of the LED.

In another embodiment of the present invention, the LED packaging structure includes a carrier, an LED chip, and an encapsulating resin. The carrier has an insulating layer and a conducting layer provided thereon. A top of the carrier is partially depressed to form a cup portion having a raised central seat upward projected from a bottom thereof. The raised central seat has a top preferably flush with or higher than the conducting layer. The LED chip is mounted on the top of the raised central seat, and the encapsulating resin encapsulates and protects the LED chip. With these arrangements, lights emitted from the top and the peripheral wall of the LED chip are not hindered by the inner wall of the cup portion and not subjected to reflection loss. Therefore, the LED chip provides better light flux and enhanced light emitting effect. Moreover, the raised central seat provides increased heat radiating area for the LED chip, enabling the LED packaging structure to have improved heat-radiating power, which further enhances the light emitting effect and the usable life of the LED.

In a further embodiment of the present invention, the LED packaging structure includes a carrier, an LED chip, an encapsulating resin, and a light-gathering hood. The carrier has an insulating layer and a conducting layer provided thereon. A top of the carrier is partially depressed to form a cup portion having a raised central seat upward projected from a bottom thereof. The raised central seat has a top preferably flush with or higher than the conducting layer. The LED chip is mounted on the top of the raised central seat, and the encapsulating resin encapsulates and protects the LED chip. The light-gathering hood is fixedly attached to the carrier corresponding to the encapsulating resin for creating an enhanced light-gathering effect. With these arrangements, lights emitted from the top and the peripheral wall of the LED chip are not hindered by the inner wall of the cup portion and not subjected to reflection loss. Therefore, the LED chip provides better light flux and enhanced light emitting effect. Moreover, the raised central seat provides increased heat radiating area for the LED chip, enabling the LED packaging structure to have improved heat-radiating power, which further enhances the light emitting effect and the usable life of the LED.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectional view showing a conventional LED packaging structure;

FIG. 2 is a sectional view showing an LED packaging structure according to a first embodiment of the present invention;

FIG. 3 is a sectional view showing an LED packaging structure according to a second embodiment of the present invention; and

FIG. 4 is a sectional view showing an LED packaging structure according to a third embodiment of the present invention.

### DETAILED DESCRIPTION OF THE PREFERRED EMBODIMENTS

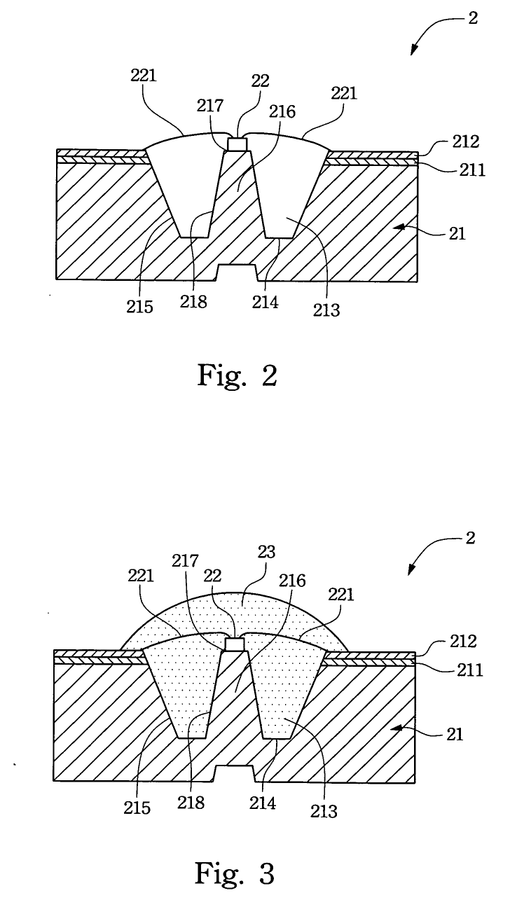

Reference is made to FIG. 2, a cross-sectional view showing an LED packaging structure 2 according to a first embodiment of the present invention. As shown, the packaging structure 2 includes a carrier 21 and an LED chip 22.

The carrier 21 is made of a material with high radiating power, such as gold, silver, copper, tungsten, molybdenum, tin, zinc, indium, aluminum, etc., or an alloy thereof. On a top surface of the carrier 21, there is provided an insulating layer 211. A conducting layer 212 consisting of conducting circuits is further provided on the insulating layer 211. The top surface of the carrier 21 is partially depressed to form a cup portion 213 having a raised central seat 216 projected from a bottom 214 thereof. A top surface 217 of the raised central seat 216 is preferably flush with or higher than a top surface of the conducting layer 211.

The LED chip 22 is mounted on the top surface 217 of the raised central seat 216, and is electrically connected at two electrodes thereof to the conducting layer 212 of the carrier 21 via two conductors 221. When the circuits on the conducting layer 212 are supplied with electrical power, lights are emitted from the top and the peripheral wall of the LED chip 22.

In the LED packaging structure 2, since the LED chip 22 is mounted on the top surface 217 of the raised central seat 216, a focus of light source from the LED chip 22 is located at an increased height. Moreover, since the top surface 217 of the raised central seat 216 is higher than the cup portion 213, lights emitted from the top and the peripheral wall of the LED chip 22 are not blocked by an inner wall surface 215 of the cup portion 213 or subjected to reflection interference by the inner wall surface 215 to cause any light loss. That is, the lights emitted from the LED chip 22 have the lowest light loss and an increased light flux, and accordingly, enhanced brightness and lighting effect.

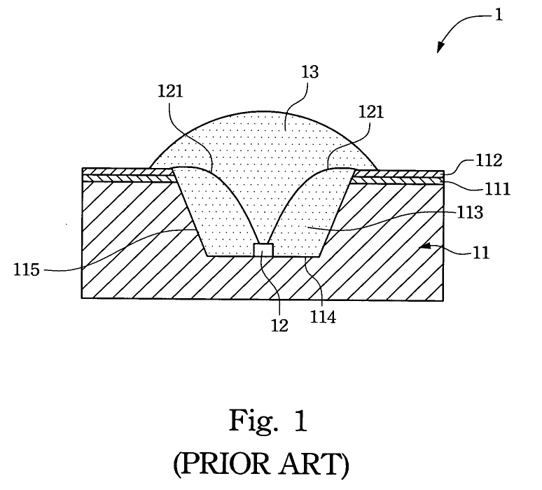

Further, since the LED chip 22 is mounted on and in contact with the top surface 217 of the raised central seat 216, a peripheral wall 218 of the raised central seat 216, the bottom 214 of the cup portion 213, and the inner wall surface 215 of the cup portion 213 that are integrally connected to the top surface 217 together form a heat radiating area for the LED chip 22. The heat radiating area provided on the carrier 21 is obviously larger than that provided on the carrier 11 of the conventional LED packaging structure 1 of FIG. 1, and therefore advantageously improves the heat-radiating power of the LED packaging structure 2 and accordingly, the light-emitting effect of the LED chip 22 to thereby increase the useable life of the LED chip 22.

FIG. 3 is across-sectional view showing an LED packaging structure 2 according to a second embodiment of the present invention. As shown, the second embodiment is generally structurally similar to the first embodiment, except that it further includes an encapsulating resin 23 applied to encapsulate and protect the LED chip 22 and the conductors 221. The second embodiment enables the same good light-emitting effect and heat radiating effect as the first embodiment.

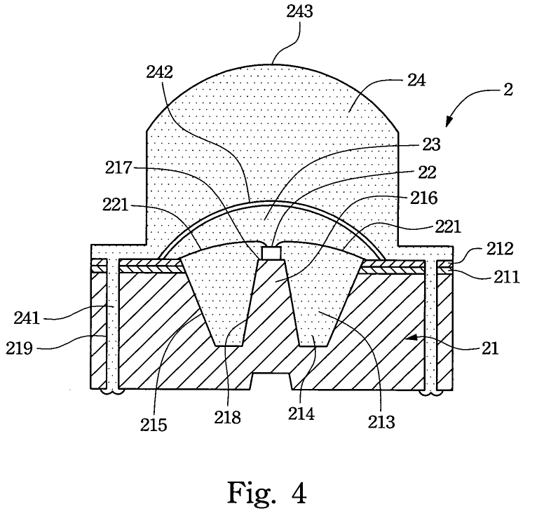

FIG. 4 is across-sectional view showing an LED packaging structure 2 according to a third embodiment of the present invention. As shown, the third embodiment is generally structurally similar to the second embodiment, except that it further includes a light-gathering hood 24 fixedly attached to the carrier 21 corresponding to the encapsulating resin 23. The light-gathering hood 24 is fixedly attached to the carrier 21 either by bonding to or engaging with the carrier 21.

In the case of bonding to the carrier 21, an adhesive or a bonding agent is applied over a bottom of the light-gathering hood 24 to bond the same to the top of the carrier 21. In the case of engaging with the carrier 21, the light-gathering hood 24 is provided at a bottom with a plurality of downward extended insertion pins 241, and the carrier 21 is provided at corresponding positions with a plurality of through holes 219, so that the insertion pins 241 are separately downward inserted into the through holes 219 to engage the hood 24 with the carrier 21. Lower ends of the insertion pins 241 are slightly projected from a bottom of the through holes 219, and are molten, flattened, and expanded before becoming hardened, so as to fixedly attach to the bottom of the carrier 21.

The light-gathering hood 24 includes an inner wall 242 and an outer wall 243, both of which may be a curved surface, a paraboloidal surface, or a spherical surface to provide the light-gathering effect. The third embodiment enables the same good light-emitting effect and heat radiating effect as the first and the second embodiment.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light emitting diode (LED) packaging structure comprising:
a carrier having an insulating layer provided on a top surface thereof, and a conducting layer provided on a top surface of said insulating layer; the top surface of said carrier being partially depressed to form a cup portion, and said cup portion having a raised central seat upward projected from a bottom thereof; and
an LED chip mounted on a top surface of said raised central seat to electrically connect at two electrodes to said conducting layer via two conductors.

2. The LED packaging structure as claimed in claim 1, wherein said carrier is made of a material with high radiating power.

3. The LED packaging structure as claimed in claim 2, wherein said carrier is made of a material selected from the group consisting of gold, silver, copper, tungsten, molybdenum, tin, zinc, indium, and aluminum, and alloys thereof.

4. The LED packaging structure as claimed in claim 1, wherein said raised central seat has a top surface flush with the top surface of said conducting layer.

5. The LED packaging structure as claimed in claim 1, wherein said raised central seat has a top surface higher than the top surface of said conducting layer.

6. A light emitting diode (LED) packaging structure comprising:
a carrier having an insulating layer provided on a top surface thereof, and a conducting layer provided on a top surface of said insulating layer; the top surface of said carrier being partially depressed to form a cup portion, and said cup portion having a raised central seat upward projected from a bottom thereof;
an LED chip mounted on a top surface of said raised central seat to electrically connect at two electrodes to said conducting layer via two conductors; and
an encapsulating resin for encapsulating said LED chip and said conductors.

7. The LED packaging structure as claimed in claim 6, wherein said carrier is made of a material with high radiating power.

8. The LED packaging structure as claimed in claim 7, wherein said carrier is made of a material selected from the group consisting of gold, silver, copper, tungsten, molybdenum, tin, zinc, indium, and aluminum, and alloys thereof.

9. The LED packaging structure as claimed in claim 6, wherein said raised central seat has a top surface flush with the top surface of said conducting layer.

10. The LED packaging structure as claimed in claim 6, wherein said raised central seat has a top surface higher than the top surface of said conducting layer.

11. A light emitting diode (LED) packaging structure comprising:
a carrier having an insulating layer provided on a top surface thereof, and a conducting layer provided on a top surface of said insulating layer; the top surface of said carrier being partially depressed to form a cup portion, and said cup portion having a raised central seat upward projected from a bottom thereof;
an LED chip mounted on a top surface of said raised central seat to electrically connect at two electrodes to said conducting layer via two conductors;
an encapsulating resin for encapsulating said LED chip and said conductors; and
a light-gathering hood being fixedly connected to said carrier corresponding to said encapsulating resin.

12. The LED packaging structure as claimed in claim 11, wherein said carrier is made of a material with high radiating power.

13. The LED packaging structure as claimed in claim 12, wherein said carrier is made of a material selected from the group consisting of gold, silver, copper, tungsten, molybdenum, tin, zinc, indium, and aluminum, and alloys thereof.

14. The LED packaging structure as claimed in claim 11, wherein said raised central seat has a top surface flush with the top surface of said conducting layer.

15. The LED packaging structure as claimed in claim 11, wherein said raised central seat has a top surface higher than the top surface of said conducting layer.

16. The LED packaging structure as claimed in claim 11, wherein said light-gathering hood is bonded to a top of said carrier.

17. The LED packaging structure as claimed in claim 16, wherein said light-gathering hood is bonded to the top of said carrier via an adhesive or a bonding agent applied over a bottom surface of said light-gathering hood.

18. The LED packaging structure as claimed in claim 11, wherein said light-gathering hood is engaged with said carrier.

19. The LED packaging structure as claimed in claim 18, wherein said light-gathering hood is provided at a bottom with a plurality of downward projected insertion pins, and said carrier is provided with a plurality of through holes corresponding to said insertion pins, such that said insertion pins are separately downward inserted into said through holes to engage said light-gathering hood with said carrier; and lower ends of said insertion pins being slightly projected from a bottom of said through holes, and being molten, flattened, and expanded before becoming hardened, so as to fixedly attach to the bottom of said carrier.
